(19) United States
(12) Patent Application Publication
(10) Pub. No.: US 2016/0020117 A1
(43) Pub. Date: Jan. 21, 2016

(54) SCANNED PULSE ANNEAL APPARATUS AND METHODS

(71) Applicant: Applied Materials, Inc., Santa Clara, CA (US)

(72) Inventors: Aaron Muir HUNTER, Santa Cruz, CA (US); Amikam SADE, Cupertino, CA (US); Samuel C. HOWELLS, Portland, OR (US); Douglas E. HOLMGREN, Portland, OR (US); Bruce E. ADAMS, Portland, OR (US); Theodore P. MOFFITT, Hillsboro, OR (US); Stephen MOFFATT, St. Brelade (JE)

(21) Appl. No.: 14/805,232

(22) Filed: Jul. 21, 2015

Related U.S. Application Data
(60) Provisional application No. 62/027,186, filed on Jul. 21, 2014.
(60) Provisional application No. 62/112,009, filed on Feb. 4, 2015.

(51) Int. Cl. H01L 21/324; H01L 21/67; B23K 26/70; B23K 26/073; B23K 26/08; B23K 26/00; H01L 21/268; B23K 26/0622

(52) U.S. Cl. CPC H01L 21/324; H01L 21/268; H01L 21/67115; B23K 26/0622; B23K 26/0732; B23K 26/083; B23K 26/0066; B23K 26/70

(57) ABSTRACT

Apparatus, system, and method for thermally treating a substrate. A source of pulsed electromagnetic energy can produce pulses at a rate of at least 100 Hz. A movable substrate support can move a substrate relative to the pulses of electromagnetic energy. An optical system can be disposed between the energy source and the movable substrate support, and can include components to shape the pulses of electromagnetic energy toward a rectangular profile. A controller can command the source of electromagnetic energy to produce pulses of energy at a selected pulse rate. The controller can also command the movable substrate support to scan in a direction parallel to a selected edge of the rectangular profile at a selected speed such that every point along a line parallel to the selected edge receives a predetermined number of pulses of electromagnetic energy.

### RELATED APPLICATIONS

This application claims the benefit of U.S. Provisional Application Ser. No. 62/027,186, filed on Jul. 21, 2014, and claims the benefit of U.S. Provisional Application Ser. No. 62/112,009, filed Feb. 4, 2015. The aforementioned related patent applications are incorporated by reference herein in their entirety.

### FIELD OF THE INVENTION

Embodiments of the invention generally relate to a method of manufacturing a semiconductor device. More particularly, embodiments of the invention are directed to thermally processing a substrate.

### BACKGROUND

Semiconductor devices continue to shrink to meet future performance requirements. For continued scaling to be realized, engineering of doped source and drain junctions must focus on placement and movement of single atoms within a very small crystal lattice. For example, some future device designs contemplate channel regions comprising fewer than 100 atoms. With such exacting requirements, controlling placement of dopant atoms to within a few atomic radii is needed.

Placement of dopant atoms is controlled currently by processes of implanting dopants into source and drain regions of silicon substrates and then annealing the substrates. Dopants may be used to enhance electrical conductivity in a silicon matrix, to induce damage to a crystal structure, or to control diffusion between layers. Atoms such as boron (B), phosphorus (P), arsenic (As), cobalt (Co), indium (In), and antimony (Sb) may be used for enhanced conductivity. Silicon (Si), germanium (Ge), and argon (Ar) may be used to induce crystal damage. For diffusion control, carbon (C), fluorine (F), and nitrogen (N) are commonly used. During annealing, a substrate is typically heated to high temperatures so that various chemical and physical reactions can take place in multiple IC devices defined in the substrate. Annealing recreates a more crystalline structure from regions of the substrate that were previously made amorphous, and “activates” dopants by incorporating their atoms into the crystalline lattice of the substrate. Ordering the crystal lattice and activating dopants reduces resistivity of the doped regions. Thermal processes, such as annealing, involve directing a relatively large amount of thermal energy onto a substrate in a short amount of time, and thereafter rapidly cooling the substrate to terminate the thermal process. Examples of thermal processes that have been widely used for some time include Rapid Thermal Processing (RTP) and impulse (spike) annealing.

In a pulse train annealing process, energy is delivered in a series of sequential pulses of energy to allow for a controlled diffusion of dopants and the removal of damage from the substrate over a short distance within desired regions of a semiconductor device. In one example, the short distance is between about one lattice plane to tens of lattice planes. In this example, the amount of energy delivered during a single pulse is only enough to provide an average diffusion depth that is only a portion of a single lattice plane and thus the annealing process requires multiple pulses to achieve a desired amount of dopant diffusion or lattice damage correction. Each pulse may thus be said to accomplish a complete micro-anneal process within a portion of the substrate. In another example, the number of sequential pulses may vary between about 30 and about 100,000 pulses, each of which has a duration of about 1 nanosecond (nsec) to about 10 milliseconds (msec). In other examples, duration of each pulse may be less than 10 msec, such as between about 1 msec and about 10 msec, or between about 1 nsec and about 10 microseconds (μsec). In some examples, duration of each pulse may be between about 1 nsec and about 10 nsec, such as about 1 nsec.

Each micro-anneal process features heating a portion of the substrate to an anneal temperature for a duration, and then allowing the anneal energy to dissipate completely within the substrate. The energy imparted excites motion of atoms within the anneal region which is subsequently frozen after the energy dissipates. The region immediately beneath the anneal region is substantially pure ordered crystal. As energy from a pulse propagates through the substrate, interstitial atoms (dopant or silicon) closest to the ordered region are nudged into lattice positions. Other atoms not ordered into immediately adjacent lattice positions diffuse upward toward the disordered region and away from the ordered region to find the nearest available lattice positions to occupy. Additionally, dopant atoms diffuse from high concentration areas near the surface of the substrate to lower concentration areas deeper into the substrate. Each successive pulse grows the ordered region upward from the ordered region beneath the anneal region toward the surface of the substrate, and smoothes the dopant concentration profile. This process may be referred to an epitaxial crystal growth, because it proceeds layer by layer, with each pulse of energy accomplishing from a few to tens of lattice planes of annealing.

### SUMMARY

In various embodiments, an apparatus for thermally processing a substrate can include a source of pulsed electromagnetic energy. The source can pulse the energy at a rate of at least 100 Hz. The apparatus can also include a moveable substrate support. The apparatus can also include an optical system disposed between the source of electromagnetic energy and the movable substrate support. The optical system can include components to shape the pulses of electromagnetic energy toward a rectangular profile. The apparatus can include a controller that can command the source of electromagnetic energy to produce pulses of electromagnetic energy at a selected pulse rate. The controller can also command the movable substrate support to scan in a direction parallel to a selected edge of the rectangular profile at a selected speed such that every point along a line parallel to the selected edge receives a predetermined number of pulses of electromagnetic energy.

According to various embodiments, a method of processing a substrate that has a plurality of dies thereon can include scanning the substrate across an optical path of a pulsed laser source. The method can also include concurrently delivering a plurality laser pulses to the substrate so that an illuminated area of a first pulse of the plurality of laser pulses overlaps with an illuminated area of a second pulse of the plurality of laser pulses, wherein each pulse of the plurality of laser pulses has a duration less than about 100 nsec and every location on the plurality of dies on the substrate receives illumination energy of at least about 250 mJ/cm².

According to various embodiments, an apparatus for thermally processing a substrate that includes a plurality of dies thereon can include a source of pulsed electromagnetic energy that pulses at a rate of at least 1,000 Hz. The apparatus can also include a moveable substrate support. The apparatus can also include an optical system disposed between the source of electromagnetic energy and the movable substrate support. The optical system includes components that shape the pulses of electromagnetic energy toward a rectangular profile. The apparatus also includes a controller configured to command the source of electromagnetic energy to produce pulses of electromagnetic energy at a selected pulse rate. The controller is also configured to concurrently command the movable substrate support to scan in a direction parallel to a selected edge of the rectangular profile at a selected speed such that every point on a plurality of dies along a line parallel to the selected edge receives a predetermined number of pulses of electromagnetic energy.

### BRIEF DESCRIPTION OF THE DRAWINGS

FIG. 1 is a schematic diagram of a thermal processing apparatus according to one embodiment.

FIG. 2A is an isometric view illustrating one embodiment of the invention in which a substrate is positioned in a first position under a pulse of electromagnetic energy.

FIG. 2B is an isometric view illustrating one embodiment of the invention in which a substrate is positioned in a second position under a pulse of electromagnetic energy.

FIG. 2C is an isometric view illustrating one embodiment of the invention in which a substrate is positioned in a third position under a pulse of electromagnetic energy.

FIG. 2D is an isometric view illustrating one embodiment of the invention in which a substrate is positioned in a fourth position under a pulse of electromagnetic energy.

FIG. 3A is a top view of a substrate with a pulse of electromagnetic energy arranged thereon in a first position.

FIG. 3B is a top view of a substrate with a pulse of electromagnetic energy arranged thereon in a second position.

FIG. 3C is a top view of a substrate with a pulse of electromagnetic energy arranged thereon in a third position.

FIG. 3D is a top view of a substrate with a pulse of electromagnetic energy arranged thereon in a fourth position.

FIG. 3E is a top view of a substrate with a pulse of electromagnetic energy arranged thereon in a fifth position.

FIG. 4 is a chart illustrating exemplary configurations for pulses of electromagnetic energy to achieve a desired table speed.

FIG. 5 is a block diagram of a method for thermally processing a substrate.

### DETAILED DESCRIPTION

In general the term “substrates” as used herein refers to objects that can be formed from any material that has some natural electrical conducting ability or a material that can be modified to provide the ability to conduct electricity. Typical substrate materials include, but are not limited to, semiconductors, such as silicon (Si) and germanium (Ge), as well as other compounds that exhibit semiconducting properties. Such semiconductor compounds generally include group III-V and group II-VI compounds. Representative group III-V semiconductor compounds include, but are not limited to, gallium arsenide (GaAs), gallium phosphide (GaP), and gallium nitride (GaN). Generally, the term “semiconductor substrates” includes bulk semiconductor substrates as well as substrates having deposited layers disposed thereon. To this end, the deposited layers in some semiconductor substrates processed by the methods of the present invention are formed by either homoepitaxial (e.g., silicon on silicon) or heteroepitaxial (e.g., GaAs on silicon) growth. For example, the methods of the present invention may be used with gallium arsenide and gallium nitride substrates formed by heteroepitaxial methods. Similarly, the invented methods can also be applied to form integrated devices, such as thin-film transistors (TFTs), on relatively thin crystalline silicon layers formed on insulating substrates (e.g., silicon-on-insulator [SOI] substrates). Additionally, the methods may be used to fabricate photovoltaic devices, such as solar cells. Such devices may comprise layers of conductive, semiconductive, or insulating materials, and may be patterned using a variety of material removal processes. Conductive materials generally comprise metals. Insulating materials may generally include oxides of metals or semiconductors, or doped semiconductor materials.

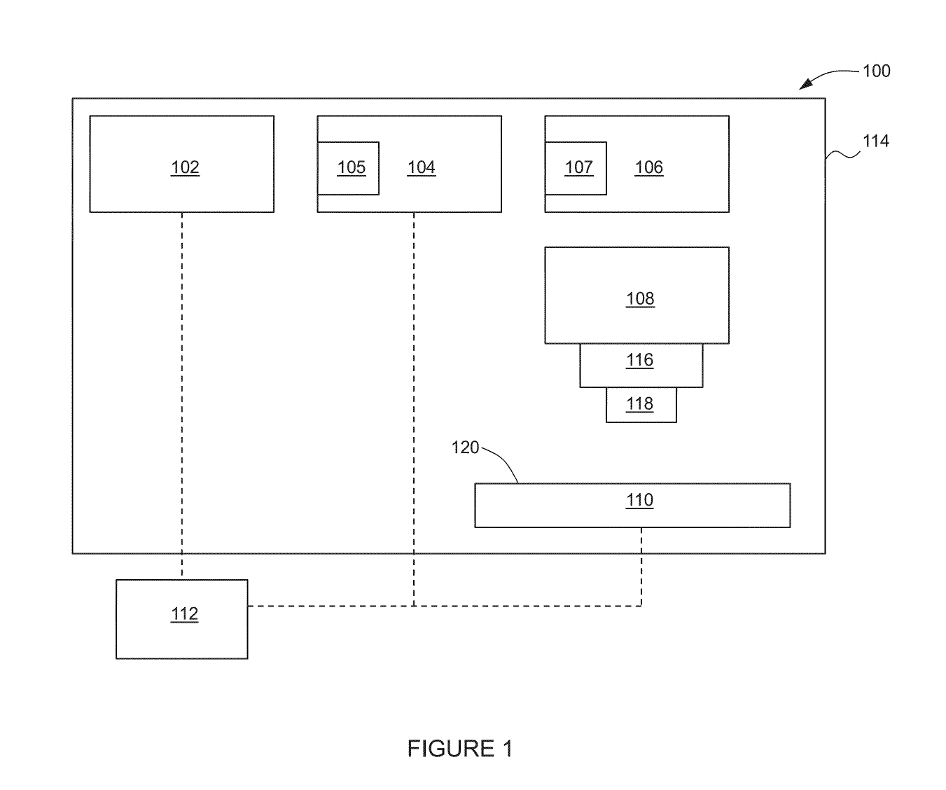

FIG. 1 is a plan view of a system 100 for laser processing of substrates. The system 100 comprises an energy input module 102 that has a plurality of pulsed laser sources producing a plurality of pulsed laser pulses, a pulse control module 104, which may include one or more pulse controllers 105, that combines individual pulsed laser pulses into combination pulsed laser pulses, and that controls intensity, frequency characteristics, and polarity characteristics of the combination pulsed laser pulses, a pulse shaping module 106, which may include one or more pulse shapers 107, that adjusts the temporal profile of the pulses of the combined pulsed laser pulses, a homogenizer 108 that adjusts the spatial energy distribution of the pulses, overlapping the combination pulsed laser pulses into a single uniform energy field, an aperture member 116 that removes residual edge non-uniformity from the energy field, and an alignment module 118 that allows precision alignment of the laser energy field with a substrate disposed on a substrate support 110. A controller 112 is coupled to the energy module 102 to control production of the laser pulses, the pulse control module 104 to control pulse characteristics, and the substrate support 110 to control movement of the substrate with respect to the energy field. An enclosure 114 typically encloses the operative components of the system 100.

The lasers may be any type of laser capable of forming short pulses, for example duration less than about 100 nsec, of high power laser radiation. Typically, high modality lasers having over 500 spatial modes with M² greater than about 30 are used. Solid state lasers such as Nd:YAG, Nd:glass, titanium-sapphire, or other rare earth doped crystal lasers are frequently used, but gas lasers such as excimer lasers, for example XeCl₂, ArF, or KrF lasers, may be used. The lasers may be switched, for example by q-switching (passive or active), gain switching, or mode locking. A Pockels cell may also be used proximate the output of a laser to form pulses by interrupting a beam emitted by the laser. In general, lasers usable for pulsed laser processing are capable of producing pulses of laser radiation having energy content between about 100 milliJoules (mJ) and about 10 Joules (J) with duration between about 1 nsec and about 100 μsec. The lasers may have wavelength between about 200 nm and about 2,000 nm, such as between about 400 nm and about 1,000 nm, for example about 532 nm. In one embodiment, the lasers are q-switched frequency-doubled Nd:YAG lasers. The lasers may all operate at the same wavelength, or one or more of the lasers may operate at different wavelengths from the other lasers in the energy module 102. The lasers may be amplified to develop the power levels desired. In most cases, the amplification medium will be the same or similar composition to the lasing medium. Each individual laser pulse is usually amplified by itself, but in some embodiments, all laser pulses may be amplified after combining.

A typical laser pulse delivered to a substrate is a combination of multiple laser pulses. The multiple pulses are generated at controlled times and in controlled relationship to each other such that, when combined, a single pulse of laser radiation results that has a controlled temporal and spatial energy profile, with a controlled energy rise, duration, and decay, and a controlled spatial distribution of energy non-uniformity. The controller 112 may have a pulse generator, for example an electronic timer coupled to a voltage source, that is coupled to each laser, for example each switch of each laser, to control generation of pulses from each laser.

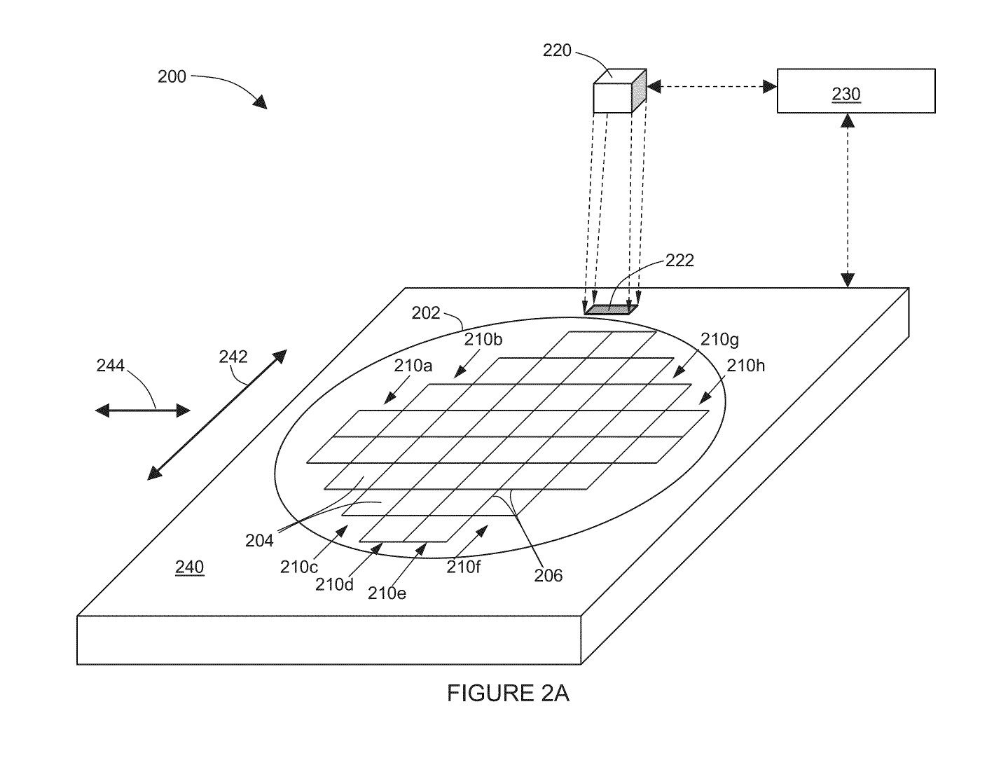

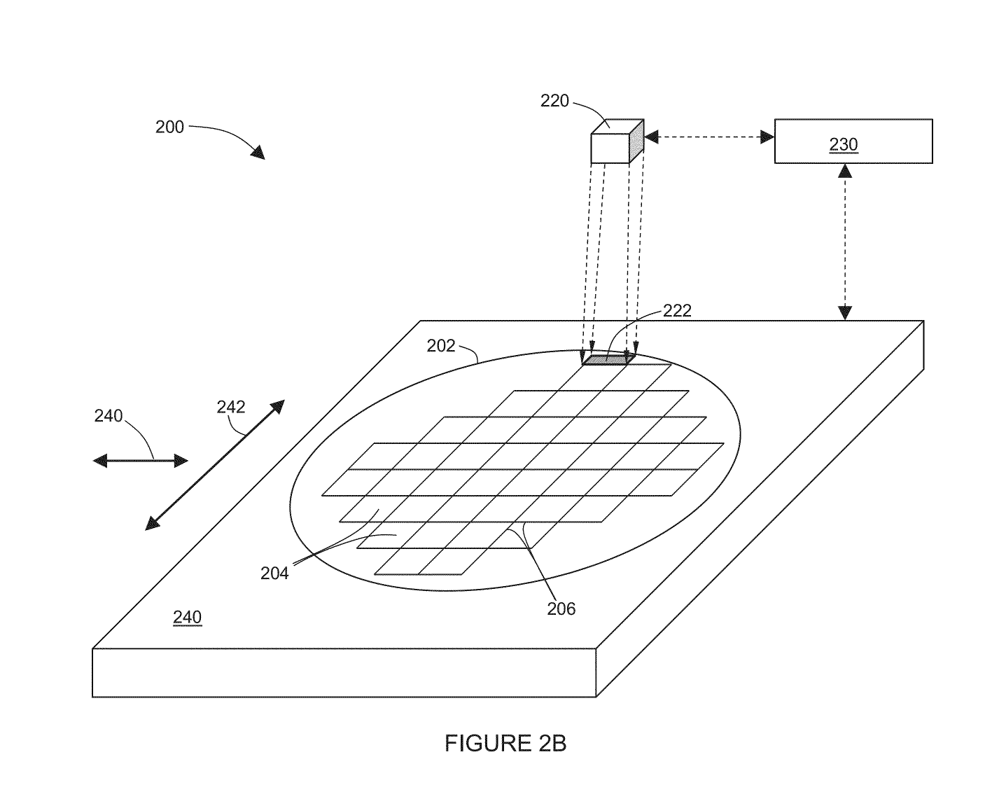

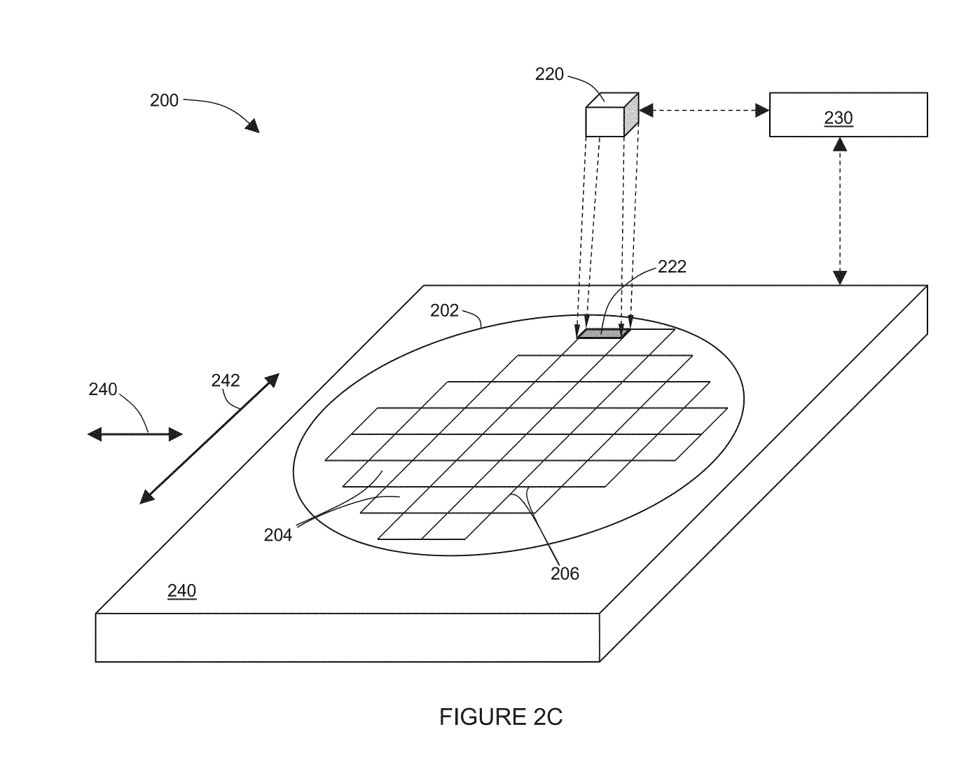

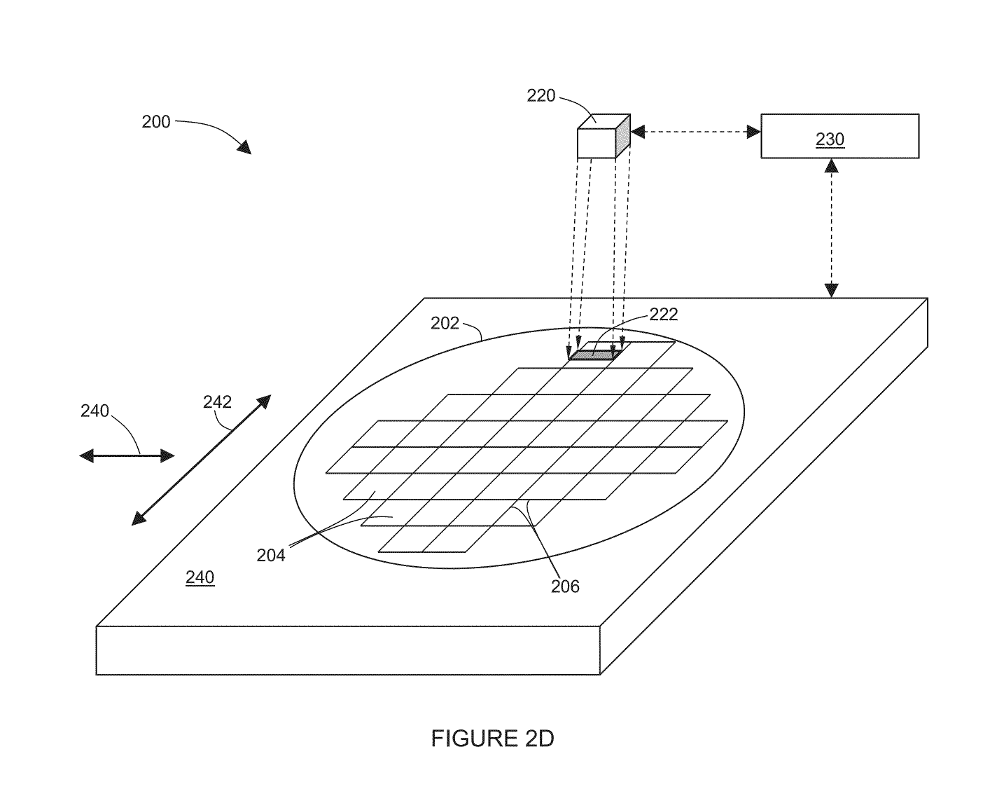

FIG. 2A illustrates an isometric view of one embodiment of the invention where an energy source 220 is adapted to project an amount of energy on a defined region, or an anneal region 222, of a substrate 202 to anneal desired regions of the substrate 202. In one example, the substrate 202 is moved under the electromagnetic energy (i.e., radiation) source 220 by translating the substrate 202 on a stage 240 (i.e., a substrate support) relative to the output of the electromagnetic energy source 220 (e.g., conventional X/Y stage, precision stages) and/or translating the output of the radiation source 220 relative to the substrate 202. Typically, one or more conventional electrical actuators (e.g., linear motor, lead screw and servo motor), which may be part of a separate precision stage (not shown), are used to control the movement and position of substrate 202. Conventional precision stages that may be used to support and position the substrate 202 may be purchased from Parker Hannifin Corporation, of Rohnert Park, Calif.

In one aspect, the anneal region 222, and radiation delivered thereto, is sized to match a first dimension of a die 204 (e.g., forty “die” 204 are shown in FIGS. 2A-2D), or semiconductor devices (e.g., memory chip), that are formed on the surface of the substrate 202. In one aspect, the first dimension of the anneal region 222 is aligned and sized to fit within the “kerf” or “scribe” lines 206 that define the boundary of each die 204 on the substrate. For example, a dimension between kerfs 206 (in the direction of arrow 244) may be 25 mm or 33 mm, so the first dimension of the anneal region 222 can be 25 mm or 33 mm, respectively. A second dimension (in the direction of arrow 242) of the anneal region 222 can be smaller than the first dimension. For example, the second dimension could be approximately 250 μm. In one embodiment, prior to performing the annealing process, the substrate 202 is aligned to the output of the energy source 220 using alignment marks typically found on the surface of the substrate 202 and other conventional techniques so that the anneal region 222 can be adequately aligned to the die 204 on the substrate 202. As shown in FIGS. 2A-2D, the table 240 can be moved, for example scanned, in the direction of arrow 242 to move the substrate 202 under the anneal region 222 such that a row (or column) of die 204 passes under the anneal region 222. For example, the substrate 202 has eight columns 210a-210h, and FIGS. 2A-2D illustrate a portion of column 210d passing under the anneal region 222 The table 240 can move in the direction of arrow 244 to move between the columns 210a-210h of die 204. As the electromagnetic energy source 220 delivers pulses of electromagnetic energy to the anneal region 222 at a first rate, the table 240 can move at a second rate so that every point on a die 204 in a column or row receives a predetermined number of electromagnetic pulses. In various embodiments, the electromagnetic energy source 220 and table 240 can be connected to a controller 230 that commands and coordinates pulses of energy from the electromagnetic energy source 220 and movement of the table 240. In various embodiments, the electromagnetic energy source 220 and the table 240 can be separately controlled by one or more dedicated controllers, and the controller 230 coordinates the pulses of electromagnetic energy and the movement of the table 240.

As shown in FIG. 2A, an anneal process can begin with the table 240 positioned such that the anneal region 222 is not impinging on the substrate 202. In various embodiments, the anneal process may begin with the anneal region 222 impinging on a portion of the substrate 202 that does not include a die 204. FIG. 2A illustrates the anneal region 222 impinging on the table 240 and aligned with column 210d of the die 204. As discussed above and in greater detail below, the electromagnetic energy source 220 can pulse electromagnetic energy onto the anneal region 222 at a first rate, such as 10,000 times per second (10,000 Hz). As shown in FIGS. 2B-2D, as the electromagnetic energy source 220 pulses electromagnetic energy, the table 240 can move the substrate 202 in the direction of arrow 242 such that the anneal region 222 passes over every point in the column 210d of die and each point in the column 210d receives a predetermined number of pulses of electromagnetic energy.

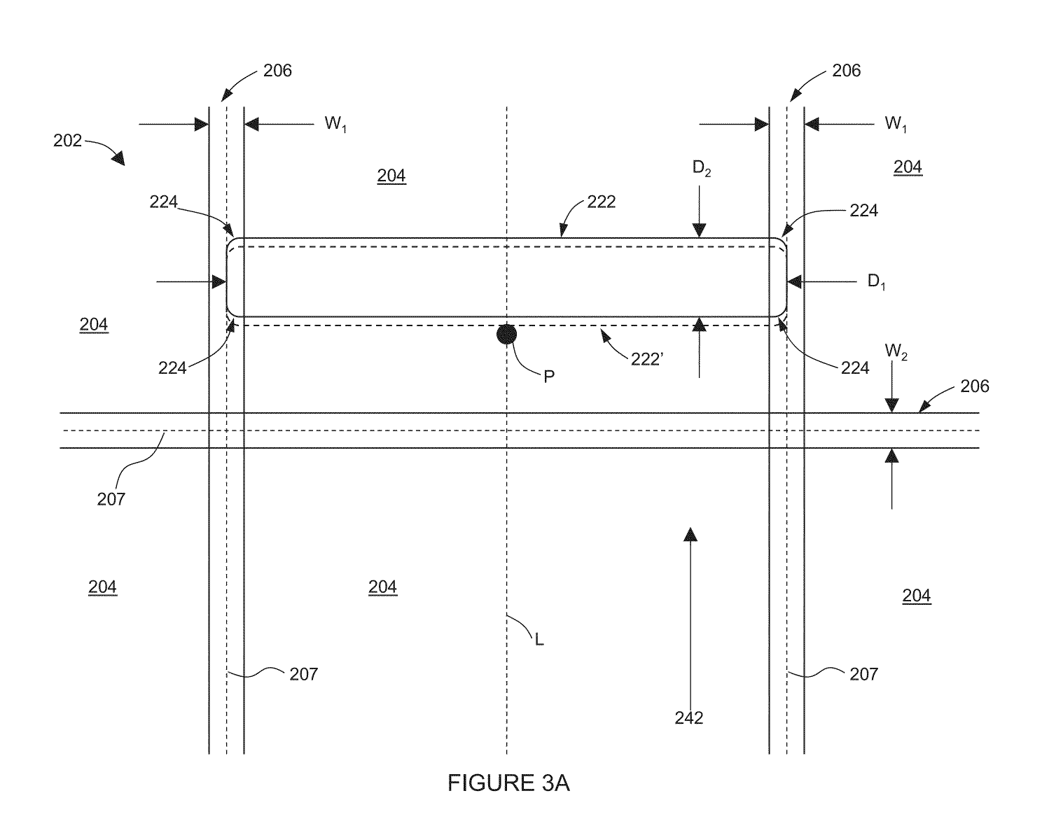

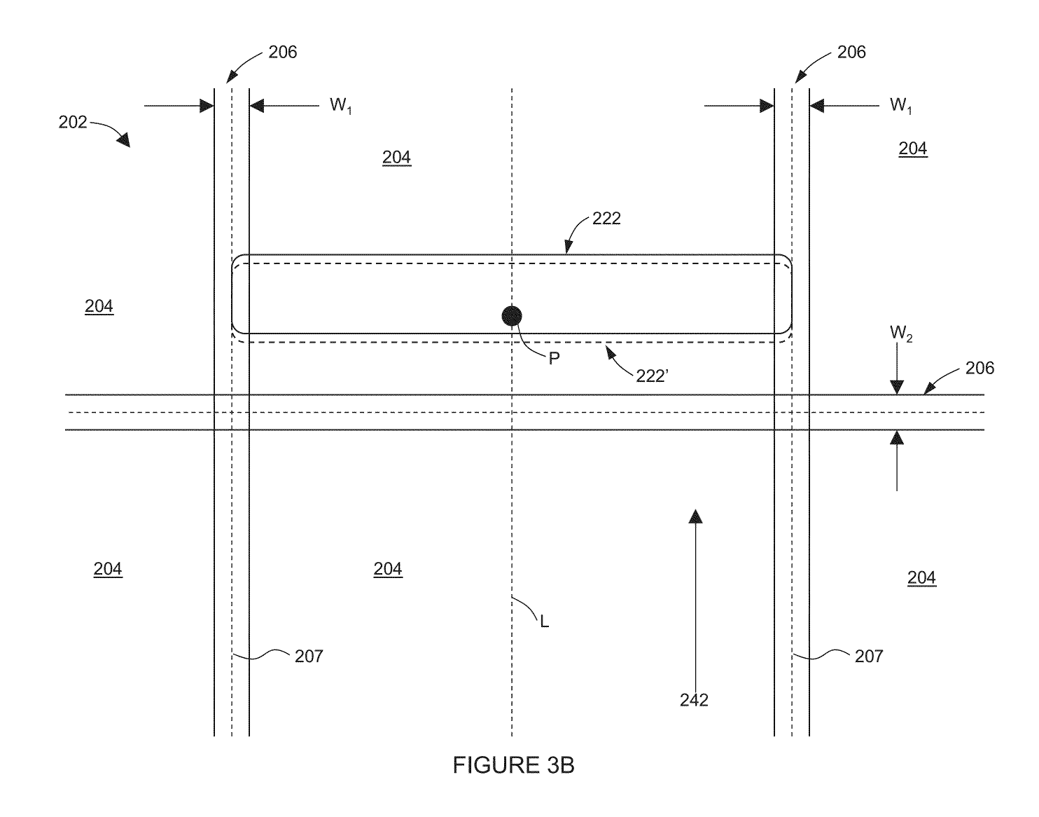

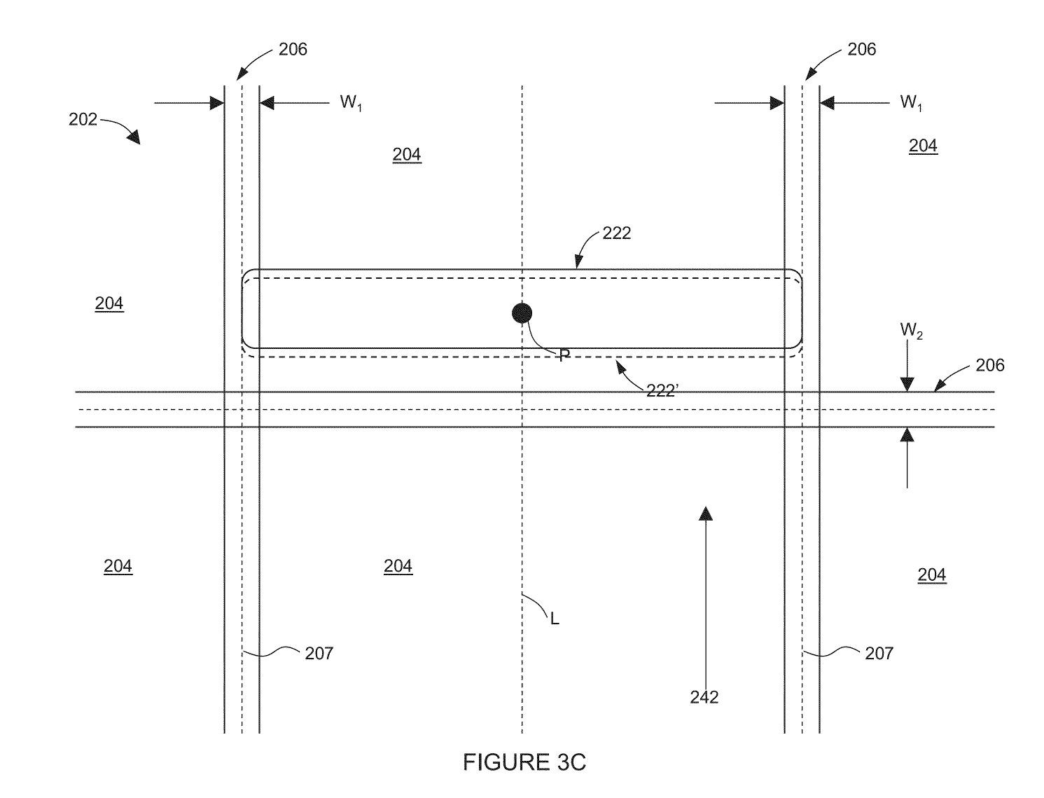

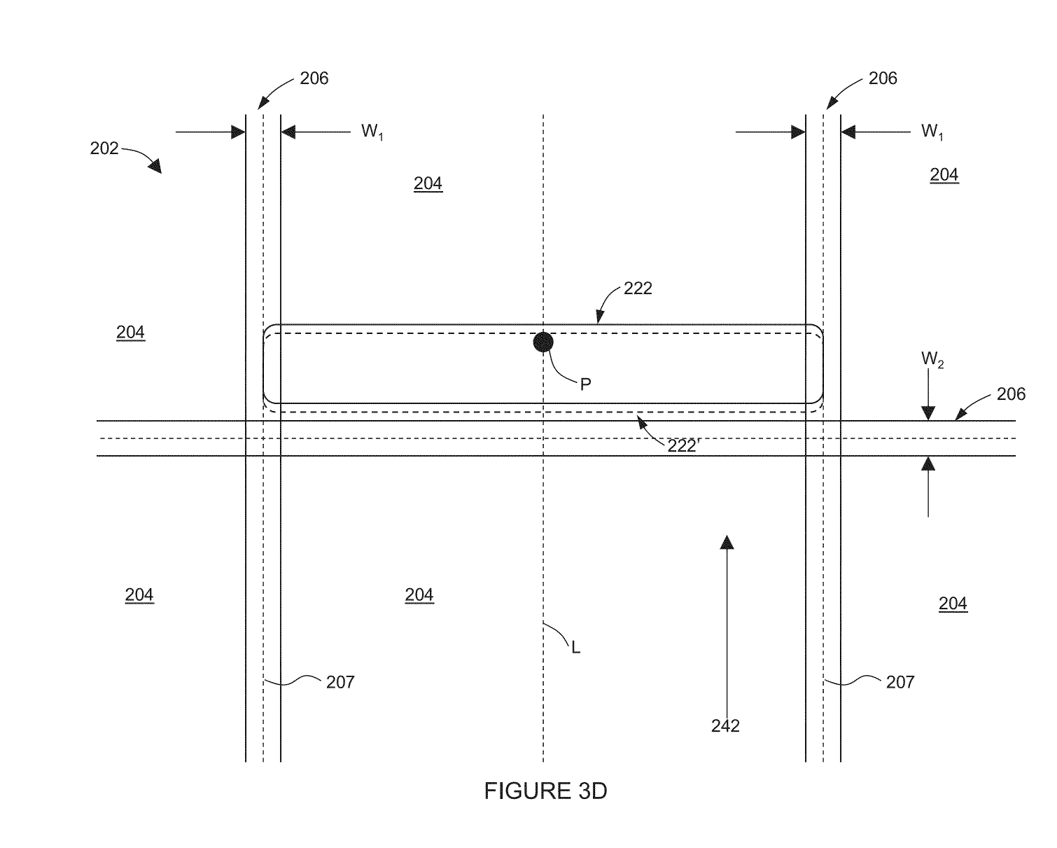

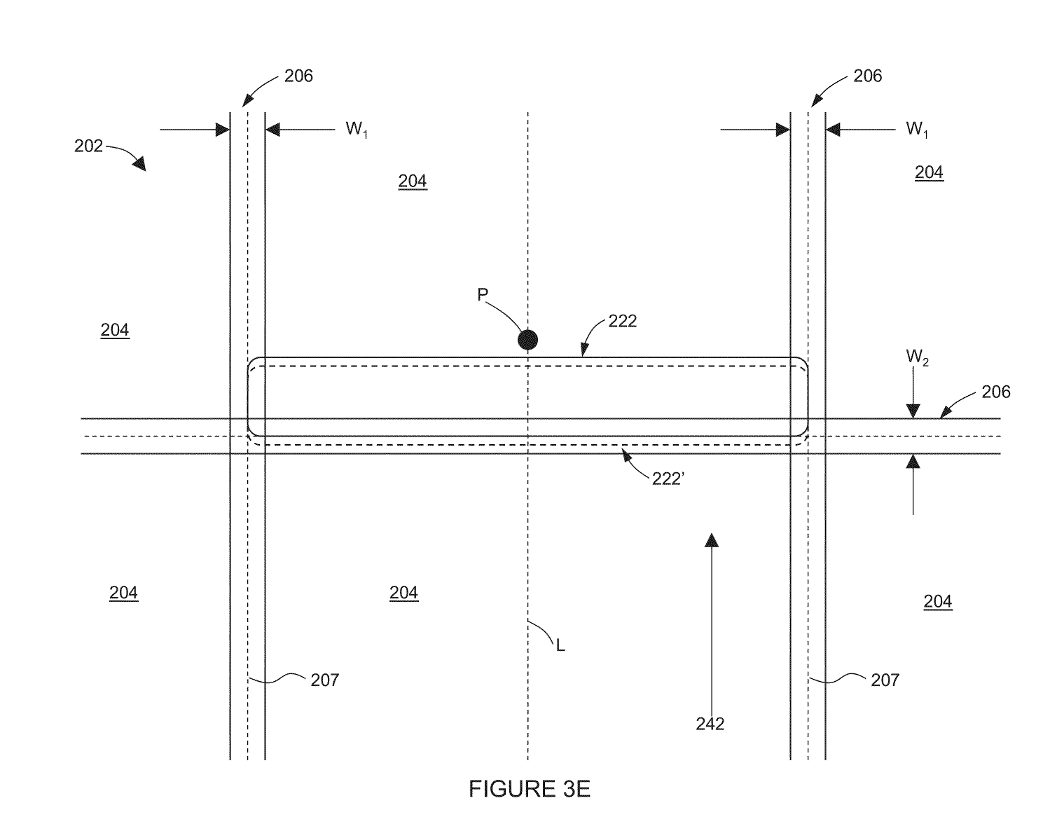

FIGS. 3A through 3E illustrate a top view of a portion of the substrate 202 shown in FIGS. 2A through 2D. The portion of the substrate 202 shown includes portions of six die 204 and kerfs 206 therebetween. The kerfs 206 can define widths W₁ (for kerfs along a first direction) and W₂ (for kerfs along a second direction perpendicular to the first direction). The widths W₁ and W₂ can be the same or different. The anneal region 222 is impinging on the substrate 202. The anneal region 222 can have a substantially rectangular profile. The anneal region 222 includes a first dimension D₁ that can be substantially equal to a distance between kerfs 206. For example, the first dimension D₁ shown in FIGS. 3A-3E is approximately equal to a distance between midlines (indicated by broken lines 207) of the kerfs 206. For example, for certain substrates 202, the distances between midlines 207 of kerfs 206 on opposite sides of a die 204 could be 25 mm. For such substrates, the dimension D₁ can be approximately 25 mm. As another example, for certain substrates 202, the distances between midlines 207 of kerfs 206 on opposite sides of a die 204 could be 33 mm. For such substrates, the dimension D₁ can be approximately 33 mm. As described below in greater detail, a second dimension D2 of the anneal region 222 can depend on the pulse rate of the electromagnetic energy source 220, the rate of movement of the table 240 in the direction of arrow 242, and the number of pulses desired to impinge on any point (e.g., point P in FIGS. 3A-3E) of the substrate 202. In various embodiments, the second dimension D2 can be approximately 250 nanometers (nm).

As discussed above, the anneal region 222 can include a substantially (i.e., nearly) rectangular profile. The electromagnetic energy source 220 can include an optical system that can shape the electromagnetic energy to have a nearly rectangular profile. For example, the anneal region 222 may have rounded corners 224 rather than straight-edged corners. However, such rounded corners 224 will not affect the uniformity of electromagnetic energy in the anneal region 222 on the die 204 if the rounded corners 224 are located in the kerfs 206. Similarly, the anneal region 222 may not have sharp boundaries. Rather, there may be a small region surrounding the anneal region 222 in which a small amount of electromagnetic energy from the electromagnetic energy source 220 falls. However, any increase in heating of the substrate 202 is minimal relative to conductive heating caused by heat in the substrate generated by the impinging electromagnetic energy in the anneal region 222 spreading outwardly from the anneal region 222. Thus, such extraneous electromagnetic energy outside the boundaries of the anneal region 222 may be ignored.

As shown in FIGS. 3A through 3E, the table 240 and the substrate 202 can be scanned (i.e., moved) in the direction of arrow 242 at a predetermined rate so that any point (e.g., point P) receives a predetermined number of pulses of electromagnetic energy. If the table 240 and the substrate 202 are moved at a constant speed, then the anneal region 222 may “smear” across the substrate 202 during a pulse of electromagnetic energy. At the beginning of a pulse, the anneal region may be located as shown by the solid-line region 222. At the end of the pulse (e.g., 75 nanoseconds later), the substrate 202 has moved in the direction of arrow 242 such that the anneal region may be located as shown by the broken-line region 222′. However, the pulses are generally short enough that such smearing can be small, and the “smearing” can average out over multiple pulses as the substrate 202 passes under the anneal region 222.

In the example shown in FIGS. 3A through 3E, any point on a die receives three pulses of electromagnetic energy from the electromagnetic energy source 220. In various instances, each point may receive ten or more pulses of electromagnetic energy. FIG. 3A illustrates a point P on a die 204 of the substrate 202. The point P lies along a line L that is parallel to the direction of movement (indicated by arrow 242) of the table 240 and substrate 202. The placement of point P and line L are arbitrary, and are only shown for purposes of illustration. FIG. 3A illustrates a position of the substrate 202 relative to the anneal region 222 during a first electromagnetic energy pulse immediately before the point P is within the anneal region 222. FIG. 3B illustrates a position of the substrate 202 relative to the anneal region 222 during a second electromagnetic energy pulse (immediately succeeding the first electromagnetic energy pulse). During the second electromagnetic energy pulse, the point P is within a first or front portion of the anneal region 222. FIG. 3C illustrates a position of the substrate 202 relative to the anneal region 222 during a third electromagnetic energy pulse (immediately succeeding the second electromagnetic energy pulse). During the third electromagnetic energy pulse, the point P is within a second or middle portion of the anneal region 222. FIG. 3D illustrates a position of the substrate 202 relative to the anneal region 222 during a fourth electromagnetic energy pulse (immediately succeeding the third electromagnetic energy pulse). During the fourth electromagnetic energy pulse, the point P is within a third or rear portion of the anneal region 222. FIG. 3E illustrates a position of the substrate 202 relative to the anneal region 222 during a fifth electromagnetic pulse (immediately succeeding the fourth electromagnetic energy pulse). During the fifth electromagnetic energy pulse, the point P is again outside the anneal region 222. Thus, as the point P on the substrate 202 passed through the anneal region 222, the point P received three pulses of electromagnetic energy from the electromagnetic energy source 220.

In various embodiments, the energy density in the anneal region 222 can be substantially regional. For example, the energy density may be approximately the same (e.g., 250 mJ/cm²) at all points in the anneal region 222. In various other embodiments, the energy density in the anneal region 222 can vary. For example, a front portion of the anneal region 222 could have a first energy density, a middle portion of the anneal region 222 could have a second energy density, and a rear portion of the anneal region 222 could have a third energy density.

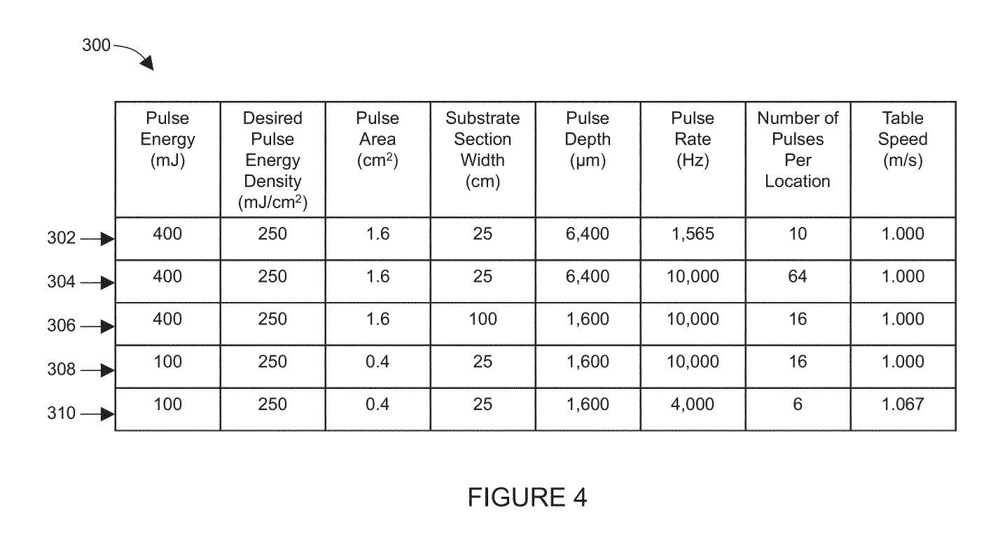

FIG. 4 is a table 300 of exemplary configurations for the use of one or more lasers to provide electromagnetic energy for pulse annealing, as described above. In each exemplary configuration, the table speed of the stage (e.g., stage 240 shown in FIG. 2A) is approximately 1 meter per second to maintain an acceptable processing rate for substrates. Row 302 of the table illustrates a first exemplary configuration in which the pulse energy of one or more lasers is 400 mJ. For example, eight 400W lasers (532 nanometer wavelength) coupled together through a laser module may produce pulses that last for 75 nanoseconds, and each pulse may output 400 mJ of energy. If the desired pulse energy density is 250 mJ/cm², then the area of the pulse impinging on the substrate (e.g., substrate 202) is 1.6 cm². In various instances, the distance between scribe lines on a substrate could be 25 mm. If the width of the pulse impinging on the substrate is 25 mm, then the depth of the pulse would be 6,400 μm to achieve an area of 1.6 cm². If 10 pulses per location (e.g., location P shown in FIGS. 3A-3E) are desired, then a table speed of 1 m/s can be achieved by using a pulse rate of 1,565 Hz. Referring to row 304 of the table 300, if a pulse rate of 10,000 Hz is desired, then a table speed of 1 m/s can be achieved by applying 64 pulses per location. Alternatively, the number of pulses per location in row 304 could be decreased, resulting in an increase in table speed.

Row 306 of the table 300 illustrates an exemplary configuration in which the width of the pulse impinging on the substrate is 100 mm. For example, the 100 mm pulse could impinge on four adjacent columns of dies simultaneously (e.g., columns 210c, 210d, 210e, and 210f of dies 204 shown in FIGS. 2A-2D). To maintain the pulse area of 1.6 cm², the pulse depth is decreased to 1,600 μm. If the pulse rate is 10,000 Hz and the desired table speed is 1 m/s, then each location on the substrate can receive 16 pulses.

Rows 308 and 310 of the table 300 illustrate exemplary configurations in which the pulse energy of one or more lasers is 100 mJ. To maintain the desired 250 mJ/cm² pulse energy density, the pulse area is decreased to 0.4 cm². If the width of the pulse impinging on the substrate is 25 mm, then the resulting pulse depth is 1,600 μm. In row 308, the pulse rate is 10,000 Hz. To maintain a table speed of 1 m/s, each location on the substrate can receive 16 pulses. Referring to row 310, if the pulse rate is decreased to 4,000 Hz, each location on the substrate can receive 6 pulses while achieving a 1 m/s table speed.

The exemplary configurations shown in the table 300 of FIG. 4 are merely illustrations. Various other configurations, which meet the throughput speeds, required number of pulses, etc. for a particular application are contemplated by this disclosure. In particular, the exemplary embodiments shown in FIG. 4 are all predicated on a table speed of 1 m/sec. If other table speeds are desired, the various characteristics and parameters may be changed accordingly.

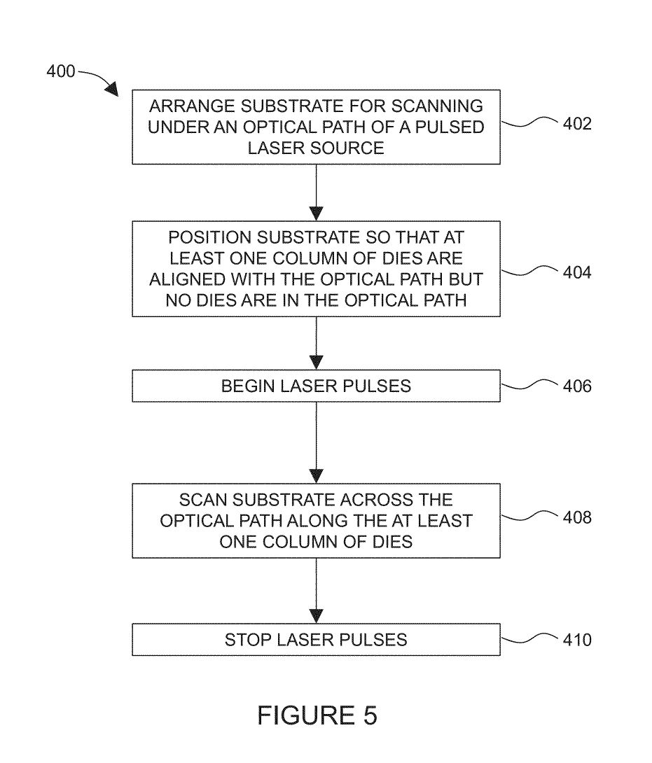

FIG. 5 illustrates a block diagram of a method 400 for thermally processing a substrate. In block 402, the substrate is arranged for scanning under an optical path of a pulsed laser source. For example, a substrate (e.g., substrate 202 shown in FIGS. 2A-2D) could be placed on a stage (e.g., stage 240 shown in FIGS. 2A-2D) that is movable relative to an optical path (e.g., anneal region 222 shown in FIGS. 2A-2D). In block 404, the substrate is positioned so that at least one column of dies on the substrate are aligned with the optical path, but none of the dies are in the optical path. For example, FIG. 2A illustrates the optical path 222 aligned with a column 210d of dies 204 on the substrate 202. However, the stage 240 is positioned such that the substrate 202 is positioned away from the optical path. In block 406, the laser pulses are initiated. The optical path 222 is shaped so that the laser pulses have a certain energy density, such as 250 mJ/cm². Once the laser pulses have been initiated, in block 408, the substrate is scanned across the optical path along at least one column of dies. For example, FIGS. 2A-2D illustrate the stage 240 being moved in the direction of arrow 242 such that a portion of the dies 204 in column 210d are scanned across the optical path 222. In various applications, a scan rate of at least one meter per second can be advantageous to maintain acceptable substrate output levels. After the entire column of dies has been scanned across the optical path, in block 410, the laser pulses can be stopped. The substrate can then be aligned so that a different at least one column is aligned with the optical path, and blocks 406 can be repeated for that column.

1. An apparatus for thermally processing a substrate, the apparatus comprising:
a source of pulsed electromagnetic energy that pulses at a rate of at least 100 Hz;
a moveable substrate support;
an optical system disposed between the source of electromagnetic energy and the movable substrate support, the optical system including components that shape the pulses of electromagnetic energy toward a rectangular profile; and
a controller configured to:
command the source of electromagnetic energy to produce pulses of electromagnetic energy at a selected pulse rate; and concurrently
command the movable substrate support to scan in a direction parallel to a selected edge of the rectangular profile at a selected speed such that every point along a line parallel to the selected edge receives a predetermined number of pulses of electromagnetic energy.

2. The apparatus of claim 1, wherein the pulses of electromagnetic energy comprise electromagnetic energy of 532 nanometers.

3. The apparatus of claim 1, wherein the pulses of electromagnetic energy comprise an energy density of at least 250 megajoules per square centimeter.

4. The apparatus of claim 3, wherein each point receives energy pulses for a cumulative time between 750 nanoseconds and 1,000 nanoseconds.

5. The apparatus of claim 1, wherein the pulse rate is 10,000 pulses per second.

6. The apparatus of claim 1, wherein the selected speed is 1 meter per second.

7. The apparatus of claim 1, wherein the rectangular profile defines a first dimension and a second dimension, wherein the first dimension is substantially equal to a section dimension of the substrate, wherein the second dimension is perpendicular to the first dimension, and wherein the second dimension is smaller than the first dimension.

8. The apparatus of claim 7, wherein the first dimension is one of 25 millimeters and 33 millimeters.

9. The apparatus of claim 1, wherein the controller commands the movable substrate to scan at the selected speed both during and between periods in which the source of electromagnetic energy produces pulses of electromagnetic energy.

10. A method of processing a substrate that includes a plurality of dies thereon, the method comprising:
scanning the substrate across an optical path of a pulsed laser source; and concurrently
delivering a plurality laser pulses to the substrate so that an illuminated area of a first pulse of the plurality of laser pulses overlaps with an illuminated area of a second pulse of the plurality of laser pulses, wherein each pulse of the plurality of laser pulses has a duration less than about 100 nsec and every location on the plurality of dies on the substrate receives illumination energy of at least about 250 mJ/cm² per pulse.

11. The method of claim 10, wherein scanning the substrate comprises initiating the scanning with a portion of the substrate without any dies in the optical path of the pulsed laser source.

12. The method of claim 10, wherein the optical path of a pulsed laser source has a first dimension that is substantially equal to a distance between midlines of kerfs separating adjacent columns of dies on the substrate, and wherein scanning the substrate across the optical path of the pulsed laser source comprises aligning a column of dies on the substrate with the optical path and scanning the substrate along the column of dies on the substrate.

13. The method of claim 10, wherein the optical path of a pulsed laser source has a first dimension that is substantially equal to a distance between midlines of kerfs across a plurality of columns of dies on the substrate, and wherein scanning the substrate across the optical path of the pulsed laser source comprises aligning a plurality of columns of dies on the substrate with the optical path and scanning the substrate along the plurality of columns of dies on the substrate.

14. The method of claim 10, wherein the duration of the plurality of laser pulses is between 60 nsec and 80 nsec.

15. The method of claim 10, wherein scanning the substrate comprises scanning the substrate at a rate such that every location on the plurality of dies on the substrate receives at least ten laser pulses.

16. The method of claim 10, wherein scanning the substrate comprises scanning the substrate at a rate of at least 1 m/sec.

17. An apparatus for thermally processing a substrate that includes a plurality of dies thereon, the apparatus comprising:
a source of pulsed electromagnetic energy that pulses at a rate of at least 1,000 Hz;
a moveable substrate support;
an optical system disposed between the source of electromagnetic energy and the movable substrate support, the optical system including components that shape the pulses of electromagnetic energy toward a rectangular profile; and
a controller configured to:
command the source of electromagnetic energy to produce pulses of electromagnetic energy at a selected pulse rate; and concurrently
command the movable substrate support to scan in a direction parallel to a selected edge of the rectangular profile at a selected speed such that every point on a plurality of dies along a line parallel to the selected edge receives a predetermined number of pulses of electromagnetic energy.

18. The apparatus of claim 17, wherein the pulses of electromagnetic energy comprise electromagnetic energy of 532 nanometers.

19. The apparatus of claim 17, wherein the pulses of electromagnetic energy comprise an energy density of at least 250 megajoules per square centimeter.

20. The apparatus of claim 19, wherein each point receives energy pulses for a cumulative time between 750 nanoseconds and 1,000 nanoseconds.
